(19) United States
(12) Patent Application Publication
(10) Pub. No.: US 2026/0260043 A1
(43) Pub. Date: Sep. 3, 2026

(54) METHODS AND SYSTEMS FOR PREDICTING ONE OR MORE FUTURE STATES OF AN ENTITY

(71) Applicant: Ma Robot Responsible AI Inc., Vancouver (CA)

(72) Inventors: Mo CHEN, Surrey (CA); Jacob Daniel BAYLESS, Vancouver (CA); Michael Samuel LU, Vancouver (CA); Nhat Minh BUI, Coquitlam (CA); Chong HE, Coquitlam (CA)

(21) Appl. No.: 19/564,046

(22) Filed: Mar. 11, 2026

Related U.S. Application Data
(63) Continuation of application No. PCT/CA2026/050322, filed on Feb. 27, 2026.
(60) Provisional application No. 63/764,848, filed on Feb. 28, 2025.

(51) Int. Cl. G06F 30/27

(52) U.S. Cl. CPC G06F 30/27

(57) ABSTRACT

A method for predicting one or more future states of an entity is provided. The method includes operating a processor to apply one or more activity classification models to environmental sensor data for determining at least one high-level activity engaged by the entity, generate one or more activity models for the entity based on the high-level activity, generate an intent prediction model, the intent prediction model comprising a set of possible intents for the entity, generate a plurality of action samples based on the one or more activity models and the intent prediction model, each action sample being associated with a candidate action and comprising an action probability associated with the candidate action, and generate the one or more future states based on the one or more activity models and the one or more action samples.

### CROSS-REFERENCE TO RELATED APPLICATION

The present application claims priority to U.S. provisional patent application No. 63/764,848, filed on Feb. 28, 2025, and entitled “Methods and Systems for Predicting One or More Future States of an Entity”, the entirety of which is hereby incorporated by reference.

### FIELD

The present disclosure generally relates to predicting one or more future states of an entity, particularly, for a moving entity.

### BACKGROUND

Humans and robots are increasingly sharing the same physical environments, extending beyond traditional industrial contexts to commercial and public spaces, and even, to private homes. In industrial contexts, stringent engineering and procedural safeguards are put in place to ensure the safety of occupants. For instance, workers are typically trained to ensure safety, and spatial separation is provided between robots and workers to minimize unintended contact.

However, in recent years, autonomous robots are being increasingly used to perform a variety of tasks in less controlled human environments that can also be crowded. For example, autonomous robots may be tasked with performing delivery operations in crowded city streets and transporting materials between locations in retail and hospital settings. In such settings, moving entities such as humans, pets, or vehicles may lack training to operate around robots (as well as the appreciation of such robots within the environment), and physical safety barriers are often not present as robots are being released into an environment traditionally used by humans. As a result, safety features integrated into autonomous robotic systems are becoming increasingly important to ensuring safe and efficient interactions in shared environments.

### SUMMARY

In a broad aspect, in accordance with one or more embodiments, there is generally described herein a computer-implemented method for predicting one or more future states of an entity. The method comprises operating a processor to: apply one or more activity classification models to environmental sensor data for determining at least one high-level activity engaged by the entity; generate one or more activity models for the entity based on the high-level activity; generate an intent prediction model, the intent prediction model comprising a set of possible intents for the entity, based on the one or more activity models and entity spatial data, the entity spatial data comprising at least one previous state, at least one previous action, and a current state of the entity; generate a plurality of action samples based on the one or more activity models and the intent prediction model, each action sample being associated with a candidate action and comprising an action probability associated with the candidate action; and generate the one or more future states based on the one or more activity models and the one or more action samples.

In some embodiments, the one or more activity models further comprises: a behavioral model for generating the plurality of action samples based on one or more candidate actions; a dynamic model for generating the subsequent state for each action sample, and the generating the one or more activity models further comprises: determining a behavioral model based at least on the high-level activity; and determining a dynamic model based at least on the high-level activity.

In some embodiments, the generating the intent prediction model is further based on the behavioral model, the at least one previous state, and the at least one previous action; and each possible intent of the set of possible intents comprises an intent probability value associated with an intent category of a plurality of intent categories and an intent confidence of a plurality of intent confidence.

In some embodiments, the generating the intent prediction model comprises: generating the set of possible intents for the entity based on the behavioral model, the at least one previous state, the at least one previous action, and a set of previous possible intents of the moving entity.

In some embodiments, the generating the set of possible intents comprises: for each previous possible intent of the set of previous possible intents, generating an updated possible intent based on a likelihood of the at least one previous action given by the behavioral model based on a previous intent category, a previous intent confidence, and a previous intent probability value, wherein the previous intent category, the previous intent confidence, and the previous intent probability value are associated with the previous possible intent.

In some embodiments, the generating a plurality of action samples comprises: determining a plurality of intent samples from the intent prediction model, each intent sample comprising a sampled intent probability value, a sampled intent category, and a sampled intent confidence; for each intent sample of the plurality of intent samples, determining a plurality of candidate actions; and for each candidate action, generate an action probability using the behavioral model based on the candidate action and the intent sample corresponding to the candidate action.

In some embodiments, the generating the one or more future states further comprises: determining a subsequent state corresponding to each action sample based on the dynamic model, the current state, and the candidate action for the action sample; and determining a combined contribution all action samples of the plurality of action samples.

In some embodiments, the determining a combined contribution of all action samples comprises determining a sum of a product of the action probability, the sampled intent probability value, and the corresponding subsequent state for each action sample.

In some embodiments, the environmental sensor data comprises one or more of an image data, a video data, and a text data about the entity and an environment of the entity.

In some embodiments, the method further comprises operating the processor to: receive the environmental sensor data relating to the entity and an environment of the entity collected from one or more sensors located within the environment; and apply one or more spatial recognition models to the environmental sensor data for identifying the entity spatial data.

In some embodiments, the method further comprises operating the processor to receive the entity spatial data from a spatial recognition system.

In some embodiments, the method further comprises operating the one or more sensors to collect the environmental sensor data.

In some embodiments, the method further comprises operating the processor to generate the plurality of intent categories using one or more foundation models based on the environment sensor data.

In some embodiments, the behavioral model further comprises a utility function associated with an intent category, and the generating an action probability using the behavioral model based on the candidate action and the intent sample comprises selecting a sampled utility function from a plurality of utility functions for the behavioral model based on the intent sample.

In some embodiments, the utility function comprises one of: a negative of a resulting distance after applying a potential future action of the plurality of potential future actions based on the current state; and a negative of a time to reach a destination location.

In some embodiments, the utility function corresponds to a closeness of a potential future action of the plurality of potential future actions to a desired action.

In some embodiments, the desired action is determined based on a multi-agent behavioral model.

In some embodiments, the method further comprises operating the processor to receive a set of prior environmental information from an external source, and wherein: the determining the entity spatial data further comprises using the set of prior environmental information; the determining the behavioral model is further based on the prior environmental information; and the determining a high-level activity further comprises using the set of prior environmental information.

In some embodiments, the method further comprises operating the processor to generate, using the one or more foundation models, one or more alternative intent categories for the plurality of possible intent categories based on an alternative prompt, the alternative prompt comprising a negative indication corresponding to each possible intent from the set of possible intents.

In some embodiments, the method further comprises generating, using the one or more foundation models, one or more intent sub-categories based on the plurality of possible intent categories.

In some embodiments, the one or more foundation models comprises one or more of a language model, a vision model, and a video model.

In some embodiments, a set of intent probability values, comprising the intent probability values for each possible intent of the set of possible intents, is normalized.

In some embodiments, a lower bound is set for each intent probability value.

In some embodiments, the generating the set of possible intents comprises discarding an outdated set of possible intents, the outdated set of possible intents being older than a predetermined sliding window threshold.

In some embodiments, the plurality of possible intent categories comprises an intent tree, the intent tree comprising one or more parent nodes and one or more child nodes, wherein the plurality of possible intent categories is associated with one or more parent nodes and the one or more intent sub-categories is associated with one or more child nodes.

In another broad aspect, in accordance with one or more embodiments, there is generally disclosed a non-transitory computer-readable medium having stored thereon computer program code that is executable by a processor and that, when executed by the processor, causes the processor to perform any one or more of the above-described embodiments of the method.

In another broad aspect, in accordance with one or more embodiments, there is generally disclosed a system for predicting one or more future states of an entity. The system comprises: one or more environmental sensors configured for collecting environmental sensor data for the entity; and a processor configured to: apply one or more activity classification models to the environmental sensor data for determining at least one high-level activity engaged by the entity; generate one or more activity models for the entity based on the high-level activity; generate an intent prediction model, the intent prediction model comprising a set of possible intents for the entity, based on the one or more activity models and entity spatial data, the entity spatial data comprising at least one previous state, at least one previous action, and a current state of the entity; generate a plurality of action samples based on the one or more activity models and the intent prediction model, each action sample being associated with a candidate action and comprising an action probability associated with the candidate action; and generate the one or more future states based on the one or more activity models and the one or more action samples.

In some embodiments, the one or more activity models further comprises: a behavioral model for generating the plurality of action samples based on one or more candidate actions; a dynamic model for generating the subsequent state for each action sample; and wherein the processor is further configured to: determine a behavioral model based at least on the high-level activity; and determine a dynamic model based at least on the high-level activity.

In some embodiments, the processor is further configured to: generate the intent prediction model based on the behavioral model, the at least one previous state, and the at least one previous action; and wherein each possible intent of the set of possible intents comprises an intent probability value associated with an intent category of a plurality of intent categories and an intent confidence of a plurality of intent confidence.

In some embodiments, the processor is further configured to: generate the set of possible intents for the entity based on the behavioral model, the at least one previous state, the at least one previous action, and a set of previous possible intents of the moving entity.

In some embodiments, the processor is further configured to, for each previous possible intent of the set of previous possible intents, generate an updated possible intent based on a likelihood of the at least one previous action given by the behavioral model based on a previous intent category, a previous intent confidence, and a previous intent probability value, wherein the previous intent category, the previous intent confidence, and the previous intent probability value are associated with the previous possible intent.

In some embodiments, the processor is further configured to: determine a plurality of intent samples from the intent prediction model, each intent sample comprising a sampled intent probability value, a sampled intent category, and a sampled intent confidence; for each intent sample of the plurality of intent samples, determine a plurality of candidate actions; and for each candidate action, generate an action probability using the behavioral model based on the candidate action and the intent sample corresponding to the candidate action.

In some embodiments, the processor is further configured to: determine a subsequent state corresponding to each action sample based on the dynamic model, the current state, and the candidate action for the action sample; and determine a combined contribution all action samples of the plurality of action samples.

In some embodiments, the processor is further configured to: determine a sum of a product of the action probability, the sampled intent probability value, and the corresponding subsequent state for each action sample.

In some embodiments, the environmental sensor data comprises one or more of an image data, a video data, and a text data about the entity and an environment of the entity.

In some embodiments, the processor is further configured to: receive the environmental sensor data relating to the entity and an environment of the entity collected from one or more sensors located within the environment; and apply one or more spatial recognition models to the environmental sensor data for identifying the entity spatial data.

In some embodiments, the processor is further configured to receive the entity spatial data from a spatial recognition system.

In some embodiments, the processor is further configured to generate the plurality of intent categories using one or more foundation models based on the environment sensor data.

In some embodiments, the behavioral model comprises a utility function associated with an intent category, and the processor is further configured to generate an action probability using the behavioral model based on the candidate action and the intent sample comprises selecting a sampled utility function from a plurality of utility functions for the behavioral model based on the intent sample.

In some embodiments, the utility function comprises one of: a negative of a resulting distance after applying a potential future action of the plurality of potential future actions based on the current state; and a negative of a time to reach a destination location.

In some embodiments, the utility function corresponds to a closeness of a potential future action of the plurality of potential future actions to a desired action.

In some embodiments, the desired action is determined based on a multi-agent behavioral model.

In some embodiments, the processor is further configured to: receive a set of prior environmental information from an external source, determine the behavioral model based on the prior environmental information; and determine the high-level activity by using the set of prior environmental information.

In some embodiments, the processor is further configured to: generate, using the one or more foundation models, one or more alternative intent categories for the plurality of possible intent categories based on an alternative prompt, the alternative prompt comprising a negative indication corresponding to each possible intent from the set of possible intents.

In some embodiments, the processor is further configured to generate, using the one or more foundation models, one or more intent sub-categories based on the plurality of possible intent categories.

In some embodiments, the one or more foundation models comprises one or more of a language model, a vision model, and a video model.

In some embodiments, a set of intent probability values, comprising the intent probability values for each possible intent of the set of possible intents, is normalized. In some embodiments, a lower bound is set for each intent probability value.

In some embodiments, the processor is further configured to discard an outdated set of possible intents, the outdated set of possible intents being older than a predetermined sliding window threshold.

In some embodiments, the plurality of possible intent categories comprises an intent tree, the intent tree comprising one or more parent nodes and one or more child nodes, wherein the plurality of possible intent categories is associated with one or more parent nodes and the one or more intent sub-categories is associated with one or more child nodes.

### BRIEF DESCRIPTION OF DRAWINGS

Several embodiments will now be described in detail with reference to the drawings, in which:

FIG. 1 is a block diagram of components interacting with a future state prediction system in accordance with an example embodiment;

FIG. 2 is a block diagram of an example future state prediction system in accordance with an example embodiment;

FIG. 3 is a flowchart of an example embodiment of various methods of predicting one or more potential future states of an entity;

FIG. 4 is a process diagram of an example use of an example behavioral model for generating probabilities of actions;

FIG. 5 is a process diagram of an example use of an example dynamic model for generating subsequent states;

FIG. 6A is an intent prediction model in accordance with an example embodiment;

FIG. 6B is an intent prediction model in accordance with an example embodiment;

FIG. 7 is a process diagram of an example use of a foundation model to generate intent categories; and

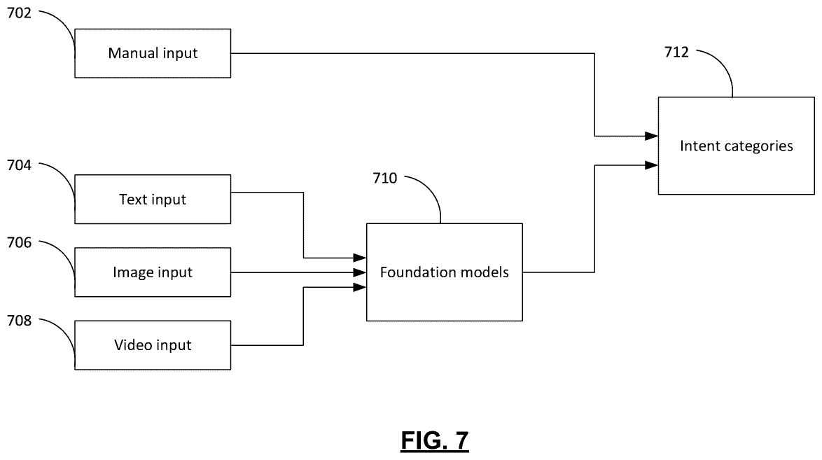

FIG. 8 is an example diagram showing potential future states of entities in accordance with an example embodiment.

The drawings, described below, are provided for purposes of illustration, and not of limitation, of the aspects and features of various examples of embodiments described herein. For simplicity and clarity of illustration, elements shown in the drawings have not necessarily been drawn to scale. The dimensions of some of the elements may be exaggerated relative to other elements for clarity. It will be appreciated that for simplicity and clarity of illustration, where considered appropriate, reference numerals may be repeated among the drawings to indicate corresponding or analogous elements or steps.

### DESCRIPTION OF VARIOUS EMBODIMENTS

Accurate path prediction of moving entities, such as humans, pets, or cars, play an important role in ensuring safe interactions between these entities and autonomous robots in shared environments. Robots operating in these environments may need to plan their trajectories to move around and accommodate for the motion of moving entities. However, the movement of these entities may exhibit significant variability due to factors such as individual intents, social conventions, and changing goals, leading to a high degree of unpredictability. This unpredictability and variability may heighten risks of collisions between robots and humans, produce inefficient movement, and may lead to general anxieties for humans operating in shared environments with robots. Thus, methods for robustly forecasting the future states of entities under uncertainty are needed.

Existing solutions may not sufficiently take into account unpredictabilities of moving entities arising from time varying intents or arising from specific environmental conditions. For example, existing approaches may overly focus on analyzing existing motion patterns of entities and extrapolating. Additionally, existing approaches may only account for geometrical constraints of surrounding environments, and may neglect advanced contextual clues that can further inform possible movements of the entity.

The presently described systems and methods are directed to the prediction of future states of unpredictable entities including, but not limited to, humans, pets, and vehicles. The presently described systems and methods may be capable of predicting the movement and future states of these entities, thus facilitating improved path planning with enhanced safety. The presently described systems and methods may generate real-time predictions relating to the entity's movements, thus allowing robots to adapt to dynamically changing conditions. The presently described systems and methods may take into account time-varying intents of the entity and adapt accordingly in real-time. The presently described systems and method may further consider a variety of possible intents tailored to the specific environment and situation the entity is in, beyond just the geometrical constraints of the environment.

The presently disclosed system and methods can take in environmental data relating to one or more entities in motion and generate probability distributions of the future states of the one or more entities. The entities can include any being or object capable of motion for which their future movements/positions can be estimated based on historical data and environmental context clues. Such entities can include humans, animals, automobiles, etc.

The presently disclosed systems and methods may provide path prediction with improved computation speed. As the analyzed environment may change rapidly, speed is needed. The presently disclosed systems and methods can produce improved computational speed by sampling from distributions that are simple to sample from, such as small categorical distributions over sets of intents and confidences or over possible actions.

The presently disclosed systems and methods can operate with little training data required about the environment it operates in. Existing methods may require some prior data in respect of the environment to function. While the presently disclosed systems and methods can leverage existing knowledge of the environment to produce greater effect and may use already trained models, it may be capable of operating without any data specific to the environment. This may provide advantages for use cases in places with little to no data available, such as in hospitals, schools, and retail environments.

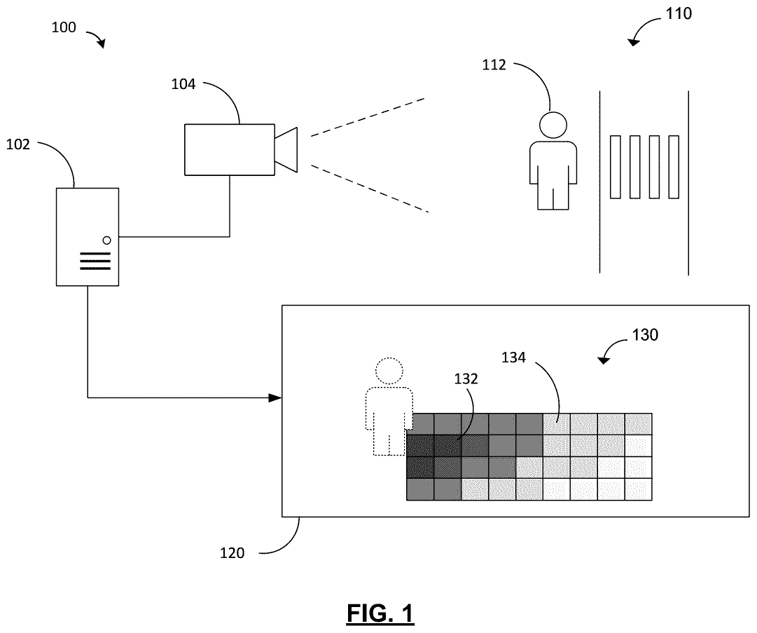

Reference is made to FIG. 1, which shows a block diagram of an example future state prediction system 100 for predicting one or more future states 130 of an entity 112. The future state prediction system 100 may include a computing device 102 and one or more environmental sensors 104. Future state prediction system 100 may be configured to capture environmental sensor data, such as image data, video data, and text data relating to an environment 110 of the entity 112 and produce one or more potential future states 130 of entity 112. A state of an entity can include any measurable property or characteristic that defines the entity's condition at some point in time. For example, the state of an entity can include a position of the entity. The state can also include velocity, orientation, rotational speed, or any other property whose evolution over time can be described by a dynamic system.

The one or more potential future states 130 of the entity may be in the form of a probability distribution showing one or more potential future positions of the entity and a predicted likelihood for each future position. The potential future states could represent the potential future position of the entity at a next timestep, such as in 1 second, or 5 seconds from now. For example, the likelihood of entity 112 to be at position 132 at the next timestep may be higher than the likelihood of entity 112 being at position 134 at the next timestep, as denoted by the color of the squares representing the positions.

Entity 112 can be any objective-oriented entity that can move based on one or more intents, which may change over time. For example, entity 112 can be a human, an animal such as a pet or livestock, a vehicle operated by a human, etc. The intent of the entity may be representative of an objective or end goal of the entity. Example intents can include moving to a desired location, waiting at a crosswalk for a traffic light, browsing the shelves at a store, avoiding an observed danger, etc. The choice of future movement of the entity 112 may be reasonably inferred from the intent of the entity. For example, if a human intends to go to a desired location, it may be inferred that the human is more likely to move in such a way that reduces the distance between the human and the desired location, rather than, for example, in a direction that points away from the desired location. As another example, if a human intends to cross a street, then the human can be assumed to be more likely to move towards the street than away from the street.

However, as described, entity 112 can have changing intents, which may depend on the context the human is in, environmental conditions, changes in attention, or other factors that may introduce variability. For example, a human may have an intent to move towards a certain location, but may notice something at a second desired location that captures the attention of the human. At that moment, the entity may change its intent, and may consequently switch directions to moving towards the second desired location. This may especially be of concern when dealing with entities such as animals or young children, which may exhibit more frequent changes in intent than, say, a vehicle.

Environment 110 may be any setting in which moving entities such as humans, animals, or vehicles may be present and in which it may be desired to predict the movement of said entities. For example, environment 110 may be an environment where humans and autonomous robots may operate in common. For example, environment 110 can include commercial spaces such as malls and supermarkets, hospitality spaces such as restaurants and hotels, public spaces such as roads and squares, residential spaces such as home, and any other environment in which autonomous robots may coexist with humans.

The environment 110 may provide contextual information about the movement of the entity. For example, environment 110 may provide clues relating to the one or more potential intents of the entity within the environment. For instance, if environment 110 is a crosswalk, example intents for an entity within such an environment could include “waiting for the light”, “crossing the street”, “waiting for a car/bus”, and more. As another example, if environment 110 is a supermarket, example intents could include “picking a product”, “browsing the shelves”, “waiting in line”, “walking through the store”, and more.

Environment 110 may also provide constraints for the movement of the entity. For example, physical barriers may be present that constrain the movement of the entity. As described previously, while an entity may be presumed to generally have a higher likelihood to move in such a way that reduces a distance to a desired location, the entity may be required to, due to intermediate barriers between the entity and the desired location, first move in a direction away from the desired location.

Future state prediction system 100 may collect environmental sensor data from environmental sensors 104 relating to the environment 110 and entity 112. Environmental sensors 104 may include sensors for capturing visible images of environment 110 such as video sensors, image sensors, and stereo image sensors. For example, the environmental sensors 104 may include the ZED™ 2 AI stereo camera system by StereoLabs™ Environmental sensors 104 may additionally include other kinds of sensors for capturing information about environment 110 and entity 112, such as sound sensors, ultrasonic sensors, LiDAR, infrared sensors, temperature sensors, and any other kind of sensor capable of providing useful contextual information to inform the actions and intents of entity 112. This information may be processed at computing device 102 to generate the one or more potential future states 130.

Environmental sensors 104 can be any set of sensors configured to collect data relating to an environment of an entity for which future state prediction is desired. In some embodiments, environmental sensors can be mounted on an autonomous robot. For example, an autonomous robot can be equipped with one or more sensors for sensing its surroundings for predicting the future state of surrounding entities, which may be used to facilitate its own path planning decisions. In some embodiments, the sensors can be mounted in fixed locations observing an environment. For example, sensors 104 can include a set of cameras mounted at one or more locations within some setting, such as a set of security cameras. The described techniques for future state prediction can then be applied to entities observed by the security system cameras.

The environmental sensor data captured by the environmental sensors 104 may be processed at computing device 102 to produce a set of possible intents for entity 112. Sensors 104 may be in communication with computing device 102 to transfer the captured data. Sensors 104 can communicate with computing device 102 through wired means such as ethernet, coaxial cabling, twin-axial cabling, fiber optics, and any other suitable means. Additionally or alternatively, wireless communication means, including protocols for radiofrequency communications such as WiFi, Bluetooth, 5G, or any other suitable communication, can be used. Environmental sensor data such as videos and images of the settings of the entity may be analyzed to produce a list of possible intents for the entity in the setting. Computing device 102 may include one or more foundation models for performing the analysis. For example, a number of different models capable of accepting different modalities may be used, which may accept inputs such as images depicting the environment, videos of the environment, sounds, text describing the environment, and may produce a text output of the list of possible intents based on the input data.

In some embodiments, the environmental sensor data can be used to determine at least one high-level activity engaged by the entity. A high-level activity may be a “mode of operation” of an entity that affects the dynamics of its motion. The high-level activity may include any number of categories to describe the mode of operation of an entity. For example, in some embodiments, the high-level activity can include numerous specific categories such as “running”, “walking”, “walking while looking at a phone”, “crawling”, etc. An activity classification model can be used to process the environmental sensor data to identify the high-level activity. The activity classification can be any model configured to take in the environmental sensor data to determine a classification of the depicted high-level activity. For example, the activity classification model can include various machine learning-based techniques for human action recognition, as is known in the art. In some embodiments, the high-level activity can be divided into fewer or simpler-to-define categories. For example, the high-level activities can include just two categories, with one for slower motion and one for faster motion.

Note that the high-level activity may be distinguished from the intent of an entity. For example, an entity may intend to move towards location A, but may move towards location A in accordance with a variety of high-level activities, such as by running, walking, crawling, jumping, etc. In this case, the intent may inform the likelihoods of the various travel directions of the entity, while the high-level activity may be indicative of the possible range of motion of the entity.

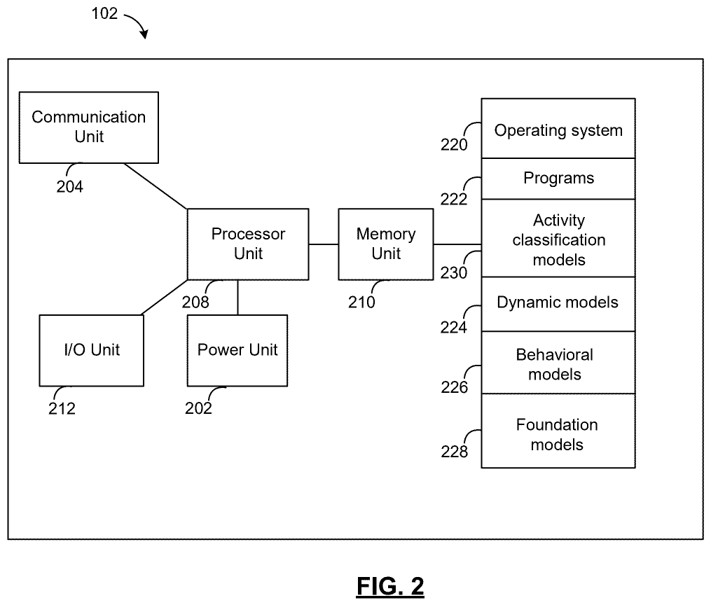

Reference is next made to FIG. 2 in conjunction with FIG. 1, which shows a block diagram of an example computing device 102 in accordance with one or more embodiments. Computing device 102 includes a power unit 202, communication unit 204, processor unit 208, I/O unit 212, and memory unit 210.

Computing device 102 can be any computing device, including a single-board computer, personal computer, laptop computer, server, mobile phone, tablet, or any such similar type of device. In some embodiments, computing device 102 can be an edge computing device integrated within an autonomous robot to facilitate future state prediction for entities around the autonomous robot. For example, computing device 102 can be a lightweight computing device capable of performing AI and edge computing tasks with efficient energy consumption, such an embedded computing board such as the NVIDIA™ Jetson™, Google Coral™, Raspberry Pi™. However, any available implementation of computing device 102 can be used. For example, in other embodiments, computing device 102 can include a central computing device connected to multiple distributed users. For example, computing device 102 can be a central computer or server connected to multiple autonomous robots, which may share the computing device 102 for use in predicting future states of entities operating in their respective environments.

Processor unit 208 can include any processing unit suitable for lightweight general-purpose computing, parallel processing, and machine-learning tasks. Processor unit 208 may be suitable for performing tasks requiring parallel processing, such as real-time machine learning inference tasks. Processing unit 208 can include multiple processing devices, such as a central processing unit (CPU) and a graphics processing unit (GPU). For example, processing unit 208 can include ARM™-based CPUs such as the Intel™ Cortex™ series or the NVIDIA™ Tegra™ series, or any other CPU of similar capabilities. Additionally or alternatively, processing unit 208 can also include one or more GPUs, such as one or more NVIDIA™ CUDA™ cores, or any other GPU of similar capabilities.

Power unit 202 may include hardware components for providing power to computing device 102. Power unit 202 can include power supplies and integrated circuits configured to accept input power from a source and distribute the power to hardware components of computing device 102.

Communication unit 204 can include hardware components for providing connectivity to computing device 102. For example, communications unit 204 can include hardware for providing connectivity via Ethernet, Wi-Fi, 5G, Bluetooth, USB, HDMI, serial interfaces, and any other external communications standard/protocol as may be required to communicate with devices and networks.

I/O unit 212 can include hardware components for interfacing with external device and peripherals. For example, I/O unit 212 can include general purpose input/output pins for interfacing with sensors and mechanical actuators. I/O unit 212 can also include hardware for connecting interface devices to configure the computing device 102.

Memory unit 210 can include hardware for storing programs, data, and software code. Memory unit 210 can include volatile storage such as random-access memory, flash storage such as eMMC, hard drives including HDDs and SSDs, and external removable storage devices such as microSD cards or USB flash drives.

Memory unit 210 may have stored upon it operating system 220, programs 222, dynamic models 224, behavioral models 226, foundation models 228, and activity classification models 230.

Operating system 220 can be any software for operating the computing device 102. Operating system 220 can be configured to interface between software and hardware components, manage software and hardware resources, and provide common services for computer programs. Operating system 220 can include any operating system as is known in the art compatible with processing device 102, such as Linux™, Android™, macOS™, Windows™, and more.

Programs 222 may include computer readable instructions for performing a variety of computational tasks on computing device 102.

Activity classification models 230 can include models for determining a high-level activity. Activity classification models 230 can take as input environmental sensor data such as images and videos, and return a classification of a high-level activity as output. For example, a video of a person in motion may be provided, and the activity classification model may determine a high-level activity as “running” or “walking” or “crawling”. In some embodiments, activity classification models 230 can include machine learning models configured to perform human activity recognition, as may be known in the art. Activity classification models 230 can include program code for operating the models, as well as any other required files for operating the models such as libraries and plugins.

For example, the activity classification model can include skeleton-based models including convolutional neural networks (CNNs), graph-based approaches, and attention mechanisms. CNN-based approaches may use 3D heat maps generated from 2D skeletons, followed by CNN layers for further processing. The activity classification model can also include video-based models, such as Action Machine, pi-ViT, and DVANet. The activity classification model can also include skeleton-visual-based approaches using multiple models or multiple input modalities, such as MMNet, STAR-Transformer, and STAR++. In some embodiments, fine-tuning can be performed on pre-trained models to target recognition of high-level activities relevant to motion. For example, classifications such as “sitting” or “waving” may not have any relevance to a future motion or state of an entity, and may, for example, be fine-tuned out of the output embedding layer to ensure that more relevant outputs are generated.

In some embodiments, the high-level activity can be divided into fewer or simpler-to-define categories. For example, the high-level activities can include just two categories, with one for slower motion and one for faster motion. In such a case, the activity classification model may be simpler than described in the previous examples. For instance, the activity classification model may simply be configured to (1) determine an estimated speed of the entity and (2) determine whether the speed exceeds a specified threshold.

Dynamic models 224 may include models for predicting a future state of an entity based on a current state and an action. Dynamic models 224 can include one or more models that can take as input a state of an entity and an action, and produce a resulting future state of the entity as an output.

In some embodiments, the dynamic model may be represented mathematically in the form p(sₜ₊₁|sₜ, aₜ; mₜ), as the transition probabilities of a Markov Decision Process, a stochastic differential equation (SDE) for probabilistic models, or in the form of an ordinary differential equation (ODE) for deterministic models. mₜ is a high-level activity of an entity, which may be determined by an activity classification model. The high-level activity can include example activities such as standing, walking, or crawling. aₜ is an action that the entity may perform. sₜ is a current state of the entity, and sₜ₊₁ is the resulting future state of the entity.

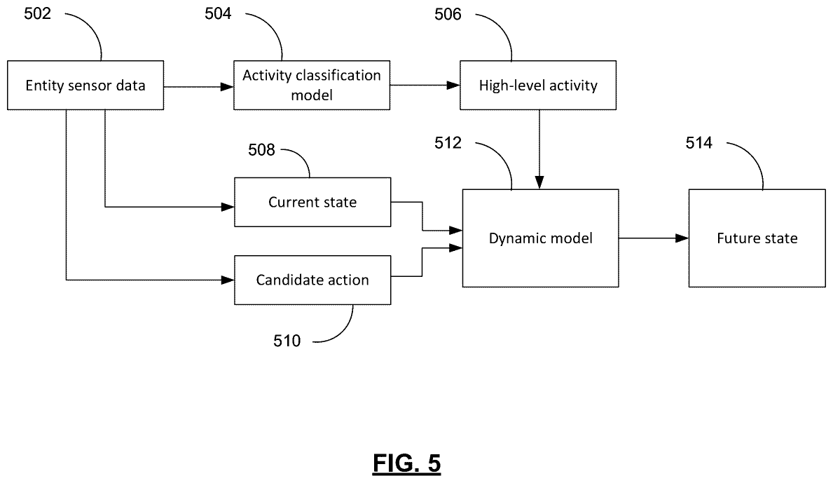

FIG. 5 shows a flowchart of a use of an example dynamic model 512 in accordance with one or more embodiments. As shown, dynamic model 512 can take in current state information 508, a candidate action 510, and a high-level activity 506 to produce a future state 514. The high-level activity 506 can be determined, for example, using activity classification model 504 based on entity sensor data 502. Activity classification model 504 may be an activity classification model 230 (FIG. 2) stored on computing device 102 (FIG. 1), and entity sensor data may be received from environmental sensor 104.

In some embodiments, dynamic models 224 can include a plurality of models, which can be selected from to model the entity based on the high-level activity. As an example, a single integrator model can be selected to model a range of slower moving human high-level activities, such as walking, which can be defined using the following system of equations, where in s is the state and u is the action:

$$s := ( x , y )$$

$$u = ( v , θ )$$

$$\dot{s} = \dot{[ \begin{matrix}\dot{x} \\ \dot{y}\end{matrix} ]} = f ( {s}_{t} , {u}_{t} ) = [ \begin{matrix}{v}_{t} cos ( {θ}_{t} ) \\ {v}_{t} sin ( {θ}_{t} )\end{matrix} ]$$

As another example, for high-level activities where the entity is likely to continue moving towards its current orientation or direction of travel, such as running or riding a bicycle, the Dubins car model may be used, which can be modeled as follows:

$$\dot{x} = V cos ( θ )$$

$$\dot{y} = V sin ( θ )$$

$$\dot{θ} = u$$

Here, the state is sₜ=(xₜ+yₜ, θₜ), where (xₜ+yₜ) is the position of the entity, and θ is an orientation of the entity. The action aₜ=(V, u) comprises a speed and a turn rate.

As yet another example, for high-level activities or systems where the rate of change of linear and angular velocity may not happen instantaneously, such as in cars, various extended Dubins car models may be used. One example is as follows:

$$\dot{x} = V cos ( θ )$$

$$\dot{y} = V sin ( θ )$$

$$\dot{V} = {u}_{1}$$

$$\dot{θ} = ω$$

$$\dot{ω} = {u}_{2}$$

Here, the state is sₜ=(xₜ, yₜ, vₜ, θₜ, ωₜ), ωₜ, θₜ,\thetaₜ, vₜ, yₜ, with each variable defined as above. The action Aₜ=(u_{1,t}, u_{2,t}), u_{2,t} comprises linear acceleration and angular acceleration.

In some embodiments, the entity itself may be considered in selecting the kinematic model to be used as a dynamic model. For example, entities likely to move in a direction corresponding to its current orientation, such as cars or vehicles, may be used with the Dubins Car model.

An entity may be described by any number of dynamic models, depending on the high-level activity the entity is currently engaged in. For example, an entity may be walking at one point in time, in which a single integrator model may be used. At another point in time, the entity may be running, in which a Dubins car model may be used.

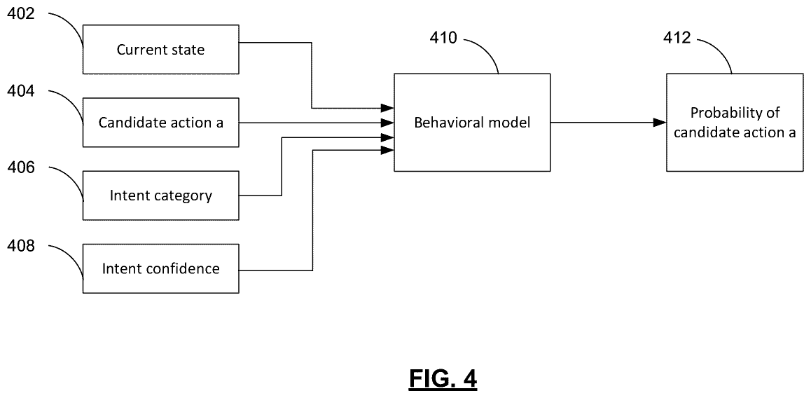

Behavioral models 226 may include models for predicting a probability of a next action given an intent. Behavioral models 226 can be stored in memory as program code, such as in the form of one or more functions that accept an action, state, and intent as input and generates a probability of the action as an output. FIG. 4 shows a schematic diagram of an example behavioral model 410, with inputs and outputs. Behavioral model 410 can be conceptually represented by p(aₜ; sₜ, βₜ, nₜ) as the probability distribution over all possible actions (aₜ) given a current state 402 (sₜ), intent confidence 408 (βₜ), and intent category 406 (nₜ). By providing a candidate action a (404), the behavioral model can produce the probability of candidate action a (412) being the next action, given the current state 402, an intent category 406 of the intent, and an intent confidence 408 of the intent. A plurality of behavioral models 226 may be available, and can be selected from to suit a particular situation of the entity. For example, the selection of the behavioral model may be based on the high-level activity of the entity, as determined using the activity classification model.

The behavioral models 226 may additionally include a utility function for determining a measure Q of how well a state and an action matches an intent. Each intent nₜ may correspond to a utility function. One or more unique utility functions may be provided. Some intents can correspond to the same utility function as other intents, while some intents can correspond to unique utility functions. A high value returned by the utility function may indicate that a state sₜ and an action aₜ are “desirable” or “closely matched” for a given intent, while a low value means that an action does not match the given intent very well. A plurality of utility functions may be available, with each potential intent of the entity being associated with a utility function.

For example, an intent to be evaluated may be the intent to reach a subset of the state space. The subset of the state space could be any region of available space that the entity wishes to reach. This region can be mathematically denoted as Γ. In such a scenario, an example utility function can be a negative of a resulting distance after applying a potential future action of the plurality of potential future actions based on the current state. For example, the utility function could entail taking the negative of a resulting distance after applying the action at from a current state sₜ. The resulting distance can be determined, for example, by determining state sₜ₊₁, and taking the difference between sₜ₊₁ and Γ. As Q is negative, a larger resulting distance results in a lower value for Q, meaning the action is less likely to match the intent, while an action that closes the distance between the entity and Γ produces a greater Q. State sₜ₊₁ can, in some instances, be determined using a dynamic model 224. Alternatively, simpler computation methods may be available. For example, if the action is simply a velocity and the state is a position, then sₜ₊₁ can be calculated from geometry.

Another example utility function could be a negative of a time to reach (TTR) a destination location—that is, Q(s)=−T(s) as defined below. For example, a value that is a negative of a resulting time to reach a goal g, which may be denoted T(s), can be determined. In free space, this may be proportional to the straight-line distance to Γ, which devolves into the previous example. In some embodiments, T(s) can be computed using methods such as optical control methods (e.g., using a toolbox like helperOC). This may involve first defining a dynamic model, and then solving a corresponding partial differential equation:

$${min}_{a} {max}_{d} ( - {( \frac{\partial T ( s )}{\partial s} )}^{T} f ( s , a , d ) - 1 ) , s ∉ g$$

$$T ( s ) = 0 , s ∈ g$$

where s is the state, T(s) is the TTR function, ƒ is the dynamic model, a is the action, and d is a disturbance (which can be used to account for errors in the dynamic model). As can be seen, an action that results in a longer time-to-reach the destination results in a lower value of Q, meaning the action may be less desirable for the intent.

As another example, a utility such as one based on a social force model may be used to consider the interaction between multiple agents. A social force model produces a desired action from a sum of several forces that represent repulsion from nearby agents, attraction from goal, and repulsion from obstacles. One example interaction is the desire of one entity to keep some distance from another entity, which can be used to model the propensity for people to keep some social distance as they navigate. In this case, an example utility function based on the social force model is

$$Q = {( d ( {s}_{other , t} ) + d ( {s}_{other , t + 1} ) )}^{2} - {v}_{other} Δ t , ( {s}_{other , t} )$$

where d(⋅) is the distance function, s_{other,t} is the state of a neighboring entity, vₒₜₕₑᵣ is the speed of the neighboring entity, and Δt is the duration of one discrete time step.

Note that in this case, the utility Q depends not only on the state of the entity being predicted, but also the state of another nearby entity. In general, the utility function may depend on any quantity that an entity accounts for while deciding on which action a to take to navigate an environment. This may include the history of recent states of multiple other entities, and the history of recent actions of multiple other entities.

In some embodiments, the closeness can be determined by a dot product between a given action with a desired action. The given action may be a vector, such as a velocity. The desired action could be a desired speed and/or velocity. In some embodiments, the desired action can be determined by a simple model, such as the current value, the extrapolated value (e.g., from a polynomial), or from a trend in a past time frame. In some embodiments, desired actions can be obtained from a multi-agent behavioral model. For example, the social force model can be used.

It should be noted that any kind of utility function can be used, corresponding to a wide variety of intents, not just goal-reaching intents. Such intents can include avoiding obstacles, continuing to move smoothly, stopping, being in/out of a social group, etc. This includes analytical models such as the aforementioned TTR utility and social force model, as well as learning-based models for prediction such as those involving neural networks like convolutional neural networks (CNNs), long short term memories (LSTMs), transformers, and graph neural networks (GNNs).

As an example, behavioral models 226 can include a noisily rational model, represented by the following relationship:

$$p ( {a}_{t} ; {s}_{t} , {β}_{t} , {n}_{t} ) ∝ exp {β}_{t} Q ( {s}_{t} , {a}_{t} ; {n}_{t} )$$

where Q represents the utility function. It can be seen that in such a model, candidate actions that produce higher values for the utility function Q may produce a higher probability according to the behavioral model. Additionally, the probability scales with Q based on the intent confidence βₜ. Intents associated with higher confidence, and therefore with larger values of βₜ, will result in a slightly higher Q value, which will produce a much higher probability due to the exponential function. As βₜ approaches infinity, the candidate action producing the highest Q (assuming Q has a unique maximum) may be the most likely to be chosen, while all other candidate actions become very unlikely to be chosen. Conversely, if βₜ is very low (approaching 0), indicating a lack of confidence about a particular intent, then the contribution of Q becomes largely irrelevant, and all actions for a given intent would produce roughly the same probability.

Intents may also apply to just a (any) subset of the action aₜ. For example, an intent representing goal reaching may only apply to the direction of travel, and be independent of the speed of travel. This may be done to ignore the travel speed preferences of the entity being predicted. This specific case may be expressed as Q_{θ}(sₜ, θₜ; g, vₜ)=d(sₜ, g)−d(sₜ₊₁, g), where d(⋅) is the distance function, and the action a=(v, θ) comprises the direction of travel θ and the speed of travel v. Here, θ is the subset of the action a, and a dependent variable of Q, while v is assumed to be known (e.g. measured as the current speed of travel).

Foundation models 228 can include pre-trained machine learning models including large language models, vision models, and video models. Foundation models can be configured to accept images, videos, text, and other data relating to an environment of an entity as input and return as output a plurality of possible intent categories. In some embodiments, a number of different models capable of accepting different modalities may be used, which may accept inputs such as images depicting the environment, videos of the environment, sounds, text describing the environment, and may produce a text output of the list of possible intents based on the input data. The outputs of the different models can be combined at a further foundation model, such as a large language model, to produce a unified list of intents. For example, if both a text-to-text and image-to-text model is used, the two models may generate differing lists, and the lists can be combined using a text-to-text model. Alternatively or additionally, multi-modal models can be used that are capable of accepting more than one modality as input simultaneously to generate the outputs. For example, commercial multi-modal models such as Claude™ Sonnet™ 3.5, GPT-4™, DeepSeek-V3™, and any other model capable of text, image, and audio processing can be used.

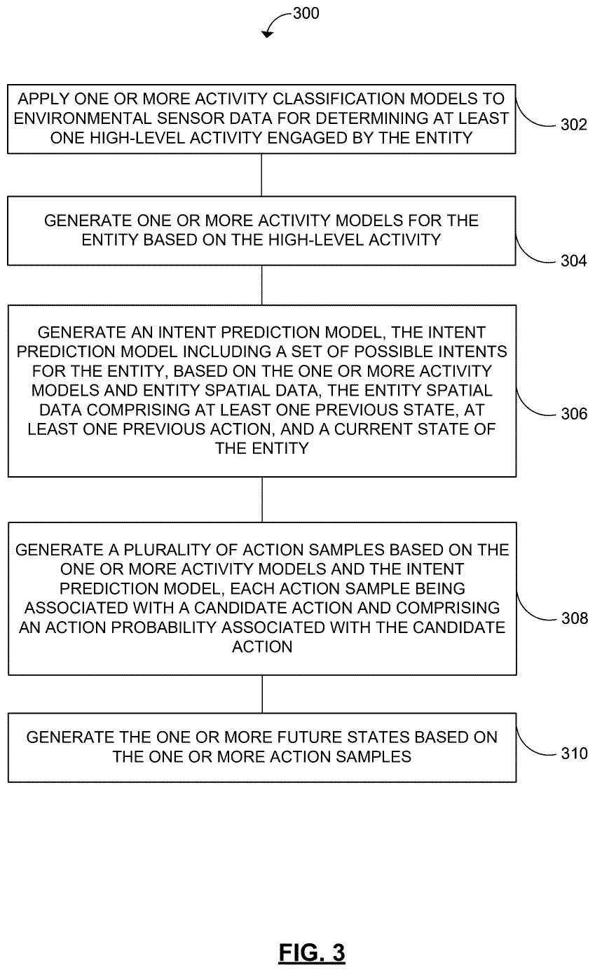

Reference is next made to FIG. 3, which shows an example method 300 for predicting one or more potential future states of an entity. Method 300 may be performed using future state prediction system 100 of FIG. 1. The entity may be, for example, entity 112, and environmental sensors 104 and computing device 102 may be used to produce probability distribution 130 of the future states of entity 112.

The method beings at 302 with operating a processor to apply one or more activity classification models to environmental sensor data for determining at least one high-level activity engaged by the entity. The processor may, for example, be the processor unit 208 of computing device 102 of FIG. 2. The environmental sensor data may include, for example, one or more of an image data, a video data, and a text data about the entity and an environment of the entity. For example, video and image data depicting the entity 112 and environment 110 may be captured by environmental sensors 104. Additionally, the environmental sensor data can include further kinds of data, such as audio, RADAR, LiDAR, and other types of data depending on the exact selection of environmental sensors 104. The activity classification model can be, for example, activity classification models 230 stored on computing device 102.

The environmental sensor data may be received from any source. In some embodiments, the method may include operating the one or more sensors to collect the environmental sensor data. In some embodiments, the environmental sensor data can be received from one or more external sources. For example, raw sensor data can be received from an external system containing sensors monitoring an area containing entities for which future path prediction is desired. The processing steps herein can then be performed, and the results may be returned to the external system.

In some embodiments, the method may include operating the processor to receive the environmental sensor data relating to the entity and an environment of the entity collected from one or more sensors located within the environment and to apply one or more spatial recognition models to the environmental sensor data for identifying entity spatial data. The entity spatial data can include one or more of a current state, a previous action, and a previous state of the entity. For example, a number of techniques can be used, as is known in the art, for determining a position and velocity from processing raw image or video data. In one example, computing device 102 may operate one or more neural network based techniques for identifying poses and positions of entities in a video and mapping the positions to a real life reference frame. The neural network techniques may extend to determining previous actions, or, the previous action can be determined from determining a previous state and a current state. For example, by knowing a first position at time A and a second position at time B, a velocity can be estimated based on the difference in the positions and the difference in the times.

In some embodiments, the method further comprises operating the processor to receive the entity spatial data from a spatial recognition system. An external spatial recognition system can be used to both capture the environmental sensor data and produce the entity spatial data. For example, a system such as the Zed™ 2 stereo camera system by StereoLabs™ can be used, which contains both image/video capture capabilities and integrated AI-based motion/spatial detection capabilities. In such instances, the entity spatial data can be directly obtained from the Zed™ 2 camera system. In some embodiments, a network of spatial recognition systems can be used. For example, many such described cameras may be installed across a monitored area. The monitored area can be large and/or contiguous. Computing units can be attached to each camera, configured to use AI-based techniques to extract the positions of entities moving around in the monitored area. The positions of at least one entity (i.e., an entity spatial) can be received and processed using the processor. in some embodiments, only the entity spatial data needs to be transferred for processing.

The method proceeds at 304 with operating the processor to generate one or more activity models for the entity based on the high-level activity. The activity models may include be any model capable of estimating the likelihoods of a future state for a given intent. In some embodiments, the activity model may include a behavioral model for determining probabilities of actions given an intent and a dynamic model for determining future states based on actions. For example, behavioral models 226 and dynamic models 224 stored in computing device 102 may be used. The generating the one or more activity models may further include determining a behavioral model based at least on the high-level activity and a possible intent from the set of possible intents and determining a dynamic model based at least on the high-level activity. For example, a behavioral model may be selected from the plurality of behavioral models 226 stored in memory of computing device 102. Similarly, a dynamic model may be selected from the plurality of dynamic models 224. For example, a noisily rational behavioral model and a single integrator model may be used.

The method proceeds at 306 with operating the processor to generate an intent prediction model, the intent prediction model comprising a set of possible intents for the entity, based on the one or more activity models and entity spatial data. The intent prediction model may be a model for determining the possible intents of the entity. In some embodiments, the set of possible intents can include a representation of the various possible intents the entity may have.

For example, since the internal intent of an entity cannot be known for certain and can only be estimated, the entity can be modeled as having some probability distribution over intent categories nₜ with some intent confidence βₜ at a time t. This model or belief of the intents can be denoted p(βₜ, nₜ). The distribution p(βₜ, nₜ) can be represented as a 2D array (look-up table) where each row corresponds to a value of βₜ and each column corresponds to a value of nₜ. Each array element specifies an intent probability value for every combination of βₜ, nₜ, representing the probability that the intent category nₜ has a confidence value of βₜ. The intent categories nₜ may be classifications of intents. Intent categories can be include such classifications as {“cross the street”, “wait for traffic light”, “go to crosswalk button”, “go to bus stop”}. The values of the intent confidence βₜ can represent how likely the intent category is to apply to the entity. Smaller values of intent indicate lower confidence that the intent category applies, and larger values mean higher confidence that the intent category applies. The intent confidence can range from 0 to ∞. In some embodiments, the intent confidences can be one of a set of predetermined values. For example, the intent confidences could be selected from a set such as {0,1,2,4,8,16}.

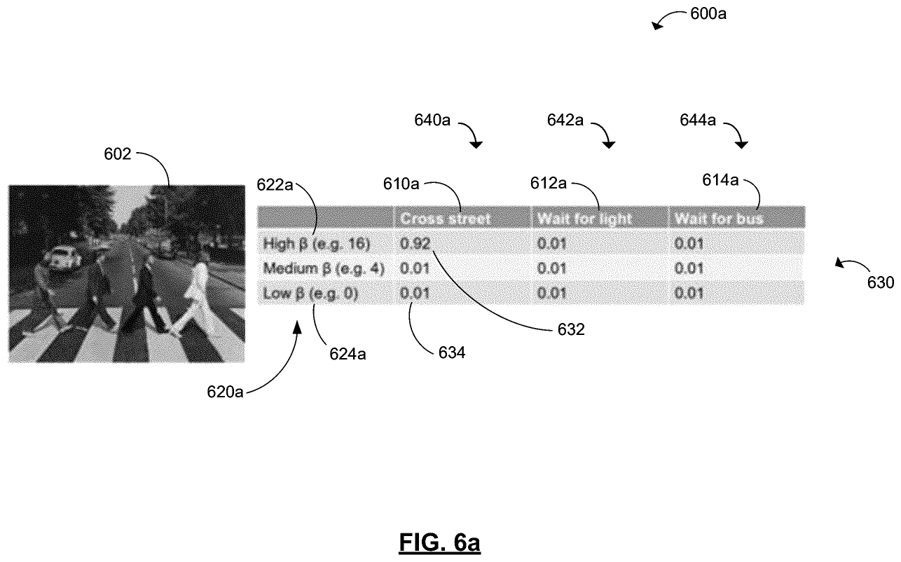

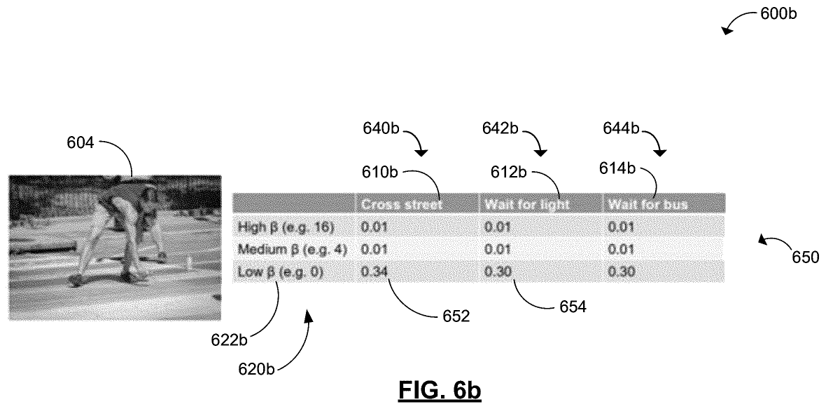

For example, FIGS. 6a and 6b show example intent prediction models 600a and 600b. Each possible intent includes an intent probability value, an intent category, and an intent confidence. For example, possible intent 640a includes intent category 610a “cross street”, intent confidences 620a, and intent probability values 630, with an intent probability value corresponding to each intent confidence and intent category.

Intent prediction model 600a may correspond to an example scenario 602. In scenario 602, the entities are crossing the street. As such, the intent probability value 632 has a relatively high value (0.92) for a high intent confidence 622a, and an intent probability value 634 has a low value (0.01) for low intent confidence 624a, indicating that the model has a high confidence that the correct intent is “cross street”.

Intent prediction model 600b may correspond to example scenario 604. In scenario 604, the entity is painting a crosswalk in the middle of the crosswalk. It can be seen, for example, that intent probabilities corresponding to low confidence value 622b are higher than for high and medium confidence values across each of the intent categories 610b “cross street”, 612b “wait for light”, and 614b “wait for bus”. This can be indicative that the model has low confidence for each of the intent categories, and that none of the intent categories are particularly applicable to the situation at hand.

The intent prediction model may be generated based on the entity spatial data and the one or more activity models. The activity model may include the behavioral model, and the entity spatial data may include the at least one previous state and the at least one previous action. For example, the generating the intent prediction model may comprise generating the set of possible intents for the entity based on the behavioral model, the at least one previous state, the at least one previous action, and a set of previous possible intents of the moving entity. For each previous possible intent of the set of previous possible intents, an updated possible intent may be generated based on a likelihood of the at least one previous action given by the behavioral model based on a previous intent category, a previous intent confidence, and a previous intent probability value, wherein the previous intent category, the previous intent confidence, and the previous intent probability value are associated with the previous possible intent.

For example, the intent prediction model, comprising the set of possible intents for the entity at time t, may be in the form of probability distribution p(βₜ, nₜ). The intent prediction model can be estimated using Bayes' rule, starting from a previous set of possible intents. For example, some initial distribution p(β₀, n₀) can be used and updated based on observations. The initial distribution could be set based on prior knowledge, such as environmental information (e.g. state of traffic light, in the case of a crosswalk environment), or set to a uniform distribution. At every time step, entity spatial data, including the last action aₜ₋₁ of the entity of interest, can be observed. Based on the behavioral model (for example, the noisily rational model as described with reference to behavior models 226 of FIG. 2), the probability of action aₜ₋₁, given by p(aₜ₋₁; sₜ₋₁, βₜ₋₁, nₜ₋₁), can be used to compute p(βₜ, nₜ) from p(βₜ₋₁,nₜ₋₁) as follows:

$$p ( {β}_{t} , {n}_{t} ) ∝ p ( {a}_{t - 1} ; {s}_{t - 1} , {β}_{t - 1} , {n}_{t - 1} ) p ( {β}_{t - 1} , {n}_{t - 1} )$$

Every entry of p(βₜ₋₁, nₜ₋₁) can then be multiplied by the corresponding value of p(aₜ₋₁; sₜ₋₁, βₜ₋₁, nₜ₋₁), which can also be represented as a 2D array of values. This is equivalent

$$p ( {β}_{t} , {n}_{t} ) ∝ p ( {β}_{0} , {n}_{0} ) {\prod }_{k = 0}^{t - 1} p ( {a}_{k} ; {s}_{k} , {β}_{k} , {n}_{k} ) .$$

to

In some embodiments, a set of intent probability values, comprising the intent probability values for each possible intent of the set of possible intents, is normalized. For example, the resulting entries of p(βₜ, nₜ) can be divided by their sum so that they add up to 1, making p(βₜ, nₜ) a normalized distribution.

In some embodiments, only a partial history of observed actions is taken into account. This is useful, for example, when the intent of the entity is rapidly changing over time. In this case, the intent distribution is given by

$$p ( {β}_{t} , {n}_{t} ) ∝ {\prod }_{k = t - N}^{t - 1} p ( {a}_{k} ; {s}_{k} , {β}_{k} , {n}_{k} ) ,$$

where N can be chosen to reflect the typical duration over which the entity maintains consistent intent. This intent distribution can be obtained incrementally via

$$p ( {β}_{t} , {n}_{t} ) ∝ p ( {β}_{t - 1} , {n}_{t - 1} ) \frac{p ( {a}_{t - 1} ; {s}_{t - 1} , {β}_{t - 1} , {n}_{t - 1} )}{p ( {a}_{t - N - 1} ; {s}_{t - N - 1} , {β}_{t - N - 1} , {n}_{t - N - 1} )} .$$

More generally, the intent distribution may be obtained from any weighted product of action probabilities over any history window. Another example of a weighting scheme is exponential averaging.

In some embodiments, the method further comprises operating the processor to generate the plurality of intent categories using one or more foundation models based on the environment sensor data. The foundation models may be foundation models 228 on computing device 102. A prompt including text, images, videos, or other supported environmental sensor data can be included to the foundation model to generate the intent categories. For example, text prompts that may be provided to generate a list of intents in a grocery store environment can include the following:
Prompt: “In a grocery store, where is a person likely to move towards?”
Response: “They person may go to the cashier, each of the aisles, or the entrance.”

Upon receiving the response, a set of intents can be generated. For example, the resulting set of intents can be in the format of: {“go to cashier #1”, “go to cashier #2”, . . . , “go to aisle #1”, “go to aisle #2”, . . . , “go to entrance”}. The foundation model may be configured to produce the set of intents in the desired format. For example, a follow-up prompt may be given to the model to generate an ordered list in array format based on the response of the model. As another example, the foundation model may be configured with function calling capabilities, whether natively or through integration with an agent, to call a function for generating and save the set of intents based on the response in, for example, a text file, csv file, a database table, etc.

As another example, an image could be provided of a grocery store, and a text prompt could be additionally provided as “In the depicted environment, where is a person likely to move towards?”. A similar chain of prompts as described in the above may follow, resulting in the generated list of intents. It will be appreciated that although a chain of prompts is shown in the above examples, one-shot prompting techniques can also be used to similar effect to produce the list of intents, as would be known to a person of skill in the art. Additionally, chain prompting techniques such as ReAct prompting can be used, for example in coordination with agents capable of function calling, to produce the final list of intents.

In some embodiments, the list of intents can be pre-determined, and the foundation models may be tasked with selecting from the predetermined list of intents. For example, the prompt to the foundation model may include a list of available intents, and instructions to select one or more intents from the list. In some embodiments, the list of available intents can be provided as an external file, and the foundation model may be configured to retrieve the list from the file and select possible intents from the pre-determined list of available intents.

In some embodiments, the input modalities can be converted to one or more secondary modalities. For example, visual inputs can be converted into text descriptions. As another example, text descriptions can be converted into longer, enhanced text descriptions based on a combination of modalities using a multi-modal foundation model.

In some embodiments, the method may include operating the processor to generate, using the one or more foundation models, one or more alternative intent categories for the plurality of possible intent categories based on an alternative prompt, the alternative prompt comprising a negative indication corresponding to each possible intent from the set of possible intents. For example, an initial list of intents may already exist, forming an existing set of intent categories. The intent categories may have been generated by the foundation model previously, or may have been previously provided to the system based on a preconfigured list. However, the observed action may not align with any of the intents. For example, as shown with the intent probability distribution 600b of FIG. 6b the intent confidence associated with each of the intent categories may be relatively low. In response, the processor may be operated to generate further intent categories.

For example, the following prompt could be provided to the foundation model:
Prompt: “The person doesn't seem to be crossing the street, moving to press the button, or waiting for the traffic light; what else could the person be doing?”
Response: “The person may be heading to the bus stop”
   In response to this, “going to bus stop” may be added as a possible intent category in the intent prediction model.

In some embodiments, one or more intent categories can be specified manually. For example, some intent categories may be considered “universal”, such as “avoid nearby agent” and “avoid nearby obstacle”. In some embodiments, sets of intents that are obtained manually or from multiple queries in different modalities can be combined together to create a larger set of intents. As will be understood, the inclusion of extra intent categories, or the omission of certain intent categories, will not necessarily impede the overall method, as confidences for each intent are explicitly modeled.

In some embodiments, the method may further comprise generating, using the one or more foundation models, one or more intent sub-categories based on the plurality of possible intent categories. For example, a hierarchy structure intents can be established. Sub-categories can be generated using the foundation model, for example using prompts such as the following:
Prompt: “In a grocery store, where is a person likely to move towards?”
Response: “A person may go to the cashier, the aisles, or the entrance.”
Resulting set of intents: {“go to cashier”, “go to aisle”, “go to entrance”}
Follow-up prompt: “Can you be more specific about the aisles?”
Response: “The different isles are ‘snacks’, ‘meat’, ‘dairy’, and ‘vegetables’.”
Resulting child set of intents under “go to aisle”: {“snacks”, “meat”, “diary”, “vegetables”}

As another example, the above prompts may be used to generate specific destination lanes as intent sub-categories under the “go to cashier” intent category.

At least some example embodiments provide robustness to outputs of all types of models, including data-driven models such as neural networks and foundation models, since each model only produces intents. The distribution over the intents is determined through comparison with actual observations in real time. This makes those embodiments not only useful for making predictions in environments that lack data, as mentioned above, but also for evaluating how consistent each model is with actual observations.

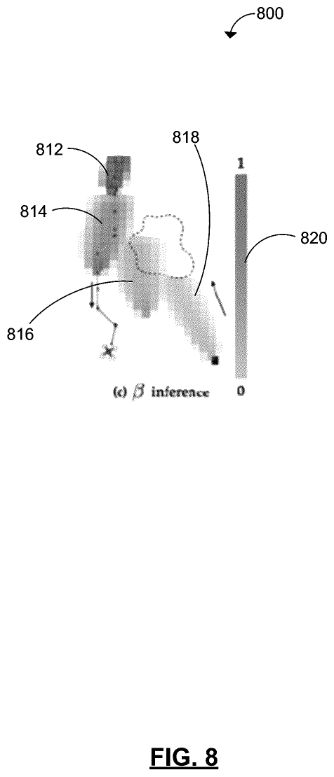

Reference is made to FIG. 8, which shows a flow diagram of generating intent categories 712. As shown, text input 704, image input 706, video input 708 may be processed by foundation models 710 to produce intent categories 712. Additionally, some intent categories may be manually specified through manual input 702.

It should be noted that when new intent categories are added, the intent probability values associated with confidences for the new possible intent may need to be initialized to an initial value.

In some embodiments, the plurality of possible intent categories may comprise an intent tree, the intent tree comprising one or more parent nodes and one or more child nodes, wherein the plurality of possible intent categories is associated with one or more parent nodes and the one or more intent sub-categories is associated with one or more child nodes. For example, the described intent categories and intent sub-categories can be arranged into a tree structure of 2D arrays. Sub-categories under an intent category can be structured as child nodes of the parent intent category. The resulting trees can then be traversed based on the confidences for each possible intent. For example, if one possible intent has very high confidence while all others have low confidence, the child intent categories of that possible intent may be included in the set of possible intents. However, the child intents may all have low confidence. In such cases, the tree may be traversed upwards, and the parent intents may be included as possible intents instead.

In some embodiments, a lower bound is set for each intent probability value. For example, a lower bound can be set to prevent the intent probability values from going below a certain threshold. This threshold captures any inherent noise in the prediction.

In some embodiments, the generating the set of possible intents comprises discarding an outdated set of possible intents, the outdated set of possible intents being older than a predetermined sliding window threshold. As the set of possible intents for the entity changes over time, only a recent history of observations may be relevant for estimating the current intent. Thus, in some embodiments, every time p(βₜ, nₜ) is updated, history older than a certain number of time steps may be discarded. For example, the distribution could be divided by p(aₜ₋ₖ₋₁; sₜ₋ₖ₋₁, βₜ₋ₖ₋₁, nₜ₋ₖ₋₁), where k is the sliding window threshold size beyond which the observations may be deemed outdated. The intent update would then follow the following relationship:

$$p ( {β}_{t} , {n}_{t} ) ∝ p ( {a}_{t - 1} ; {s}_{t - 1} , {β}_{t - 1} , {n}_{t - 1} ) p ( {β}_{t - 1} , {n}_{t - 1} ) / p ( {a}_{t - k - 1} ; {s}_{t - k - 1} , {β}_{t - k - 1} , {n}_{t - k - 1} )$$

In some embodiments, log probabilities may be used for the computation for numerical accuracy. For example, values of p(aₜ₋₁; sₜ₋₁, βₜ₋₁, nₜ₋₁) may differ by many orders of magnitude, so log probabilities can be used to turn multiplication operations into sums and division operations into differences.

Theoretically, the one or more potential future states can be generated based on the intent prediction model and the activity model, comprising the behavioral model and dynamic model, in accordance with the following relationship:

$$p ( {s}_{t + 1} \vert {s}_{t} ) = {\sum }_{{β}_{t} , {n}_{t}} p ( {β}_{t} , {n}_{t} ; {s}_{t} ) {\sum }_{{α}_{t}} p ( {s}_{t + 1} \vert {s}_{t} , {a}_{t} ; {m}_{t} ) p ( {a}_{t} \vert {s}_{t} , {β}_{t} , {n}_{t} )$$

However, as the distributions can contain a large number of discrete values, approximations may be required to numerically compute the resulting probabilities.

To this end, the method proceeds, at 308, with operating the processor to generate a plurality of action samples based on the one or more activity models and the intent prediction model, each action sample being associated with a candidate action and comprising an action probability associated with the candidate action. The generating a plurality of action samples can include: determining a plurality of intent samples from the intent prediction model, each intent sample comprising a sampled intent probability value, a sampled intent category, and a sampled intent confidence interval; for each intent sample of the plurality of intent samples, determining a plurality of candidate actions; for each candidate action, generate an action probability using the behavioral model based on the candidate action and the intent sample corresponding to the candidate action.

For example, each intent sample can be a sample value of (βₜ, nₜ) from the distribution p(βₜ, nₜ). The samples can be chosen in a way that adequately represents the entire distribution. A sampled intent probability value associated with the sampled intent category and intent confidence can be determined from the intent prediction model. For each intent sample, a plurality of candidate actions from the space of available actions can be selected. Using the behavioral model, each candidate action can be tested to determine how well it aligns with the intent sample, i.e., an action probability associated with the action given the intent sample category and intent sample confidence. This can be repeated for each intent sample, producing a plurality of action samples.

The generating an action probability using the behavioral model based on the candidate action and the intent sample can include selecting a sampled utility function from a plurality of utility functions for the behavioral model based on the intent sample. As described with reference to behavioral models 226 of FIG. 2, the utility function may determine a closeness of a potential future action of the plurality of potential future actions to a desired action. For example, depending on the intent sample chosen, the sampled intent category may be associated with a particular utility function. In using the behavioral model to generate the action samples, the behavioral model may use the utility function to determine the action probability.

The method proceeds, at 310, with operating the processor to generate the one or more potential future states based on the one or more activity models and the one or more action samples. The one or more potential future states may include one or more future states of the entity, and may include probabilities associated with each future state. For example, the one or more potential future states may include a probability distribution over a plurality of potential future states of the entity, such as distribution 130 of FIG. 1. In some embodiments, the generating the one or more potential future states comprises: determining a subsequent state corresponding to each action sample based on the dynamic model, the current state, and the candidate action for the action sample; and determining a combined contribution all action samples of the plurality of action samples.

For example, the dynamic model selected based on the identified high-level activity can be used to generate a subsequent state for each action sample. For each action sample, the candidate action used to generate the action sample may be used with the dynamic model to produce the subsequent state.

In some embodiments, the determining a combined contribution of all action samples comprises determining sum of a product of the action probability, the sampled intent probability value, and the corresponding subsequent state for each action sample. For example, the subsequent state can be multiplied with the action probability associated with its corresponding candidate action, as well as the sampled intent probability value for its' corresponding intent sample. This may be performed for each subsequent state generated for each action sample, thereby producing a set of subsequent state probabilities. The set of subsequent state probabilities can be summed, and the resulting sum may be a probability distribution of a plurality of future states.

In some embodiments, the method can be repeated for one or more other entities in the environment, thus producing multiple sets of potential future states for multiple entities. Reference is made to FIG. 8, which shows example sets of potential future states 812, 814, 816, and 818, in the form of probability distributions over future states. Each set of potential future states may correspond to a different entity. Color bar 820 shows the color corresponding to the probability at each potential future state.

Further prediction of state for multiple timesteps may be performed by repeating the above steps. For example, for a two-time step example, the following relationship may apply:

$$p ( {s}_{t + 2} \vert {s}_{t} ) = {\sum }_{{s}_{t + 1}} p ( {s}_{t + 2} \vert {s}_{t + 1} ) p ( {s}_{t + 1} \vert {s}_{t} )$$

In some embodiments, techniques such as MCMC or Gibbs sampling may be used. In some embodiments, software libraries specifically suited for numerical computations such as JAX™ may be used. In some embodiments programming frameworks suited to leveraging hardware acceleration may be used, such as HeteroCL™. In some embodiments, these algorithms may be implemented using hardware acceleration techniques, for example using GPUs to perform computations. Parallelization can greatly speed up the computation by drawing samples in parallel, and by making predictions for multiple entities in parallel.

In some embodiments, the method further comprises operating the processor to receive a set of prior environmental information from an external source, and wherein the determining the entity spatial data further comprises using the set of prior environmental information. For example, the observed environment that the entity is moving in may be known ahead of time (a priori), and this information can be pre-provided to the foundation models or activity classification system. This information may be used to augment the environmental sensor data in generating various quantities.

It will be appreciated that numerous specific details are set forth in order to provide a thorough understanding of the example embodiments described herein. However, it will be understood by those of ordinary skill in the art that the embodiments described herein may be practiced without these specific details. In other instances, well-known methods, procedures and components have not been described in detail so as not to obscure the embodiments described herein. Furthermore, this description and the drawings are not to be considered as limiting the scope of the embodiments described herein in any way, but rather as merely describing the implementation of the various embodiments described herein.

The embodiments of the systems and methods described herein may be implemented in hardware or software, or a combination of both. These embodiments may be implemented in computer programs executing on programmable computers, each computer including at least one processor, a data storage system (including volatile memory or non-volatile memory or other data storage elements or a combination thereof), and at least one communication interface. For example and without limitation, the programmable computers (referred to below as computing devices) may be a server, network appliance, embedded device, computer expansion module, a personal computer, laptop, personal data assistant, cellular telephone, smart-phone device, tablet computer, a wireless device or any other computing device capable of being configured to carry out the methods described herein.

In some embodiments, the communication interface may be a network communication interface. In embodiments in which elements are combined, the communication interface may be a software communication interface, such as those for inter-process communication (IPC). In still other embodiments, there may be a combination of communication interfaces implemented as hardware, software, and combination thereof.

Program code may be applied to input data to perform the functions described herein and to generate output information. The output information is applied to one or more output devices, in known fashion.

Each program may be implemented in a high level procedural or object oriented programming and/or scripting language, or both, to communicate with a computer system. However, the programs may be implemented in assembly or machine language, if desired. In any case, the language may be a compiled or interpreted language. Each such computer program may be stored on a storage media or a device (e.g. ROM, magnetic disk, optical disc) readable by a general or special purpose programmable computer, for configuring and operating the computer when the storage media or device is read by the computer to perform the procedures described herein. Embodiments of the system may also be considered to be implemented as a non-transitory computer-readable storage medium, configured with a computer program, where the storage medium so configured causes a computer to operate in a specific and predefined manner to perform the functions described herein.

Furthermore, the system, processes and methods of the described embodiments are capable of being distributed in a computer program product comprising a computer readable medium that bears computer usable instructions for one or more processors. The medium may be provided in various forms, including one or more diskettes, compact disks, tapes, chips, wireline transmissions, satellite transmissions, internet transmission or downloadings, magnetic and electronic storage media, digital and analog signals, and the like. The computer useable instructions may also be in various forms, including compiled and non-compiled code.

As used herein, the singular forms “a”, “an”, and “the” are intended to include the plural forms as well, unless the context clearly indicates otherwise. For example, references to performing a method using “a processor” includes performing the method in a distributed manner using more than one processor unless the context clearly indicates otherwise.

Various embodiments have been described herein by way of example only. Various modification and variations may be made to these example embodiments without departing from the spirit and scope of the invention, which is limited only by the appended claims.

1. A computer-implemented method for predicting one or more future states of an entity, the method comprising operating a processor to:
apply one or more activity classification models to environmental sensor data for determining at least one high-level activity engaged by the entity;
generate one or more activity models for the entity based on the high-level activity;
generate an intent prediction model, the intent prediction model comprising a set of possible intents for the entity, based on the one or more activity models and entity spatial data, the entity spatial data comprising at least one previous state, at least one previous action, and a current state of the entity;
generate a plurality of action samples based on the one or more activity models and the intent prediction model, each action sample being associated with a candidate action and comprising an action probability associated with the candidate action; and
generate the one or more future states based on the one or more activity models and the one or more action samples.

2. The method of claim 1, wherein the one or more activity models further comprise:
a behavioral model for generating the plurality of action samples based on one or more candidate actions;
a dynamic model for generating a subsequent state for each action sample; and
wherein the generating the one or more activity models further comprises:
determining a behavioral model based at least on the high-level activity; and
determining a dynamic model based at least on the high-level activity.

3. The method of claim 2, wherein:
the generating the intent prediction model is further based on the behavioral model, the at least one previous state, and the at least one previous action; and
each possible intent of the set of possible intents comprises an intent probability value associated with an intent category of a plurality of intent categories and an intent confidence of a plurality of intent confidence.

4. The method of claim 3, wherein the generating the intent prediction model comprises:
generating the set of possible intents for the entity based on the behavioral model, the at least one previous state, the at least one previous action, and a set of previous possible intents of the moving entity.

5. The method of claim 4, wherein the generating the set of possible intents comprises:
for each previous possible intent of the set of previous possible intents, generating an updated possible intent based on a likelihood of the at least one previous action given by the behavioral model based on a previous intent category, a previous intent confidence, and a previous intent probability value, wherein the previous intent category, the previous intent confidence, and the previous intent probability value are associated with the previous possible intent.

6. The method of claim 3, wherein the generating a plurality of action samples comprises:
determining a plurality of intent samples from the intent prediction model, each intent sample comprising a sampled intent probability value, a sampled intent category, and a sampled intent confidence;
for each intent sample of the plurality of intent samples, determining a plurality of candidate actions; and
for each candidate action, generate an action probability using the behavioral model based on the candidate action and the intent sample corresponding to the candidate action.

7. The method of claim 6, wherein the generating the one or more future states further comprises:
determining a subsequent state corresponding to each action sample based on the dynamic model, the current state, and the candidate action for the action sample; and
determining a combined contribution all action samples of the plurality of action samples.

8. The method of claim 7, wherein the determining a combined contribution of all action samples comprises determining a sum of a product of the action probability, the sampled intent probability value, and the corresponding subsequent state for each action sample.

9. The method of claim 1, wherein the environmental sensor data comprises one or more of an image data, a video data, a lidar point cloud data, and a text data about the entity and an environment of the entity.

10. The method of claim 1, further comprising operating the processor to:
receive the environmental sensor data relating to the entity and an environment of the entity collected from one or more sensors located within the environment; and
apply one or more spatial recognition models to the environmental sensor data for identifying the entity spatial data.

11. The method of claim 10, further comprising operating the processor to receive the entity spatial data from a spatial recognition system and operating the one or more sensors to collect the environmental sensor data.

12. The method of claim 3, further comprising operating the processor to generate the plurality of intent categories using one or more foundation models based on the environment sensor data.

13. The method of claim 2, wherein the behavioral model comprises a utility function associated with an intent category, and the generating an action probability using the behavioral model based on the candidate action and the intent sample comprises selecting a sampled utility function from a plurality of utility functions for the behavioral model based on the intent sample.

14. The method of claim 13, wherein the utility function corresponds to a closeness of a potential future action of the plurality of future states to a desired action.

15. The method of claim 14, wherein the desired action is determined based on a single- or multi-agent behavioral model.

16. The method of claim 1, further comprising:
operating the processor to receive a set of prior environmental information from an external source; and
determining the entity spatial data using the set of prior environmental information,
and wherein:
the determining the entity spatial data further comprises using the set of prior environmental information;
the determining the behavioral model is further based on the prior environmental information; and
the determining a high-level activity further comprises using the set of prior environmental information.

17. The method of claim 16, further comprising operating the processor to generate, using one or more foundation models based on the environment sensor data, one or more alternative intent categories or subcategories for the plurality of possible intent categories based on an alternative prompt, the alternative prompt comprising a negative indication corresponding to each possible intent from the set of possible intents; wherein the one or more foundation models comprises one or more of a language model, a vision model, and a video model.

18. The method of claim 3, wherein the generating the set of possible intents comprises discarding an outdated set of possible intents, the outdated set of possible intents being older than a predetermined sliding window threshold.

19. The method of claim 17, wherein the plurality of possible intent categories comprises an intent tree, the intent tree comprising one or more parent nodes and one or more child nodes, wherein the plurality of possible intent categories is associated with one or more parent nodes and the one or more intent sub-categories is associated with one or more child nodes.

20. A system for predicting one or more future states of an entity, the system comprising:
one or more environmental sensors configured for collecting environmental sensor data for the entity; and
a processor configured to:
apply one or more activity classification models to the environmental sensor data for determining at least one high-level activity engaged by the entity;
generate one or more activity models for the entity based on the high-level activity;
generate an intent prediction model, the intent prediction model comprising a set of possible intents for the entity, based on the one or more activity models and entity spatial data, the entity spatial data comprising at least one previous state, at least one previous action, and a current state of the entity;
generate a plurality of action samples based on the one or more activity models and the intent prediction model, each action sample being associated with a candidate action and comprising an action probability associated with the candidate action; and
generate the one or more future states based on the one or more activity models and the one or more action samples.

21. A non-transitory computer readable medium having stored thereon computer program code that is executable by a processor and that, when executed by the processor, causes the processor to perform a method for predicting one or more future states of an entity, the method comprising operating the processor to:
apply one or more activity classification models to environmental sensor data for determining at least one high-level activity engaged by the entity;
generate one or more activity models for the entity based on the high-level activity;
generate an intent prediction model, the intent prediction model comprising a set of possible intents for the entity, based on the one or more activity models and entity spatial data, the entity spatial data comprising at least one previous state, at least one previous action, and a current state of the entity;
generate a plurality of action samples based on the one or more activity models and the intent prediction model, each action sample being associated with a candidate action and comprising an action probability associated with the candidate action; and
generate the one or more future states based on the one or more activity models and the one or more action samples.
